(19) United States
(12) Patent Application Publication
(10) Pub. No.: US 2025/0048820 A1
(43) Pub. Date: Feb. 6, 2025

(54) MICRO LED AND MICRO LED DISPLAY PANEL

(71) Applicant: JADE BIRD DISPLAY (SHANGHAI) LIMITED, SHANGHAI (CN)

(72) Inventors: Zhichen GU, Shanghai (CN); Weisin TAN, Shanghai (CN)

(21) Appl. No.: 18/789,637

(22) Filed: Jul. 30, 2024

(30) Foreign Application Priority Data
Jul. 31, 2023 (WO) PCT/CN2023/110284

(51) Int. Cl. H01L 33/62; H01L 25/075; H01L 33/20; H01L 33/38; H01L 33/40; H01L 33/46

(52) U.S. Cl. CPC H01L 33/62; H01L 25/0753; H01L 33/20; H01L 33/385; H01L 33/40; H01L 33/46

(57) ABSTRACT

A micro LED includes a bonding layer, a P-N structure provided on the bonding layer, wherein the P-N structure comprises a P type semiconductor layer, an N type semiconductor layer and a light emitting layer formed between the P type semiconductor layer and the N type semiconductor layer; a top conductive layer formed on the P-N structure; and a doped P type contact layer, wherein if the P-N structure is a P-side up structure, a doped P type contact layer is provided between the N type semiconductor layer and the bonding layer, or if the P-N structure is an N-side up structure, the doped P type layer is provided between the N type semiconductor layer and the top conductive layer.

### CROSS-REFERENCE TO RELATED APPLICATIONS

The present disclosure claims the benefits of priority to PCT Application No. PCT/CN2023/110284, filed on Jul. 31, 2023, which is incorporated herein by reference in its entirety.

### TECHNICAL FIELD

The present disclosure generally relates to micro LED manufacturing technology, and more particularly, to a micro LED and a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

A micro LED display panel is manufactured by integrating an array of thousands or even millions of micro LEDs with an integrated circuitry (IC) backplane. Each pixel of the micro LED display panel is formed by one or more micro LEDs. The micro LED display panel can be a mono-color or multi-color panel. In particular, for a multi-color LED panel, each pixel may further include multiple sub-pixels respectively formed by multiple micro LEDs, each of which corresponds to a different color. For example, three micro LEDs respectively corresponding to red, green, and blue colors may be superimposed to form one pixel. The different colors can be mixed to produce a broad array of colors.

Current micro LED technology faces several challenges, for example, improving ohmic contact of the micro LED.

### SUMMARY OF THE DISCLOSURE

Embodiments of the present disclosure provide a micro LED. The micro LED includes: a bonding layer; a P-N structure provided on the bonding layer, wherein the P-N structure comprises a P type semiconductor layer, an N type semiconductor layer, and a light emitting layer formed between the P type semiconductor layer and the N type semiconductor layer; a top conductive layer formed on the P-N structure; and a doped P type contact layer, wherein if the P-N structure is a P-side up structure, the doped P type contact layer is provided between the N type semiconductor layer and the bonding layer; or if the P-N structure is an N-side up structure, the doped P type contact layer is provided between the N type semiconductor layer and the top conductive layer.

Embodiments of the present disclosure also provide a micro LED display panel. The micro LED display panel includes an integrated circuit (IC) backplane comprising a bottom pad array, the bottom pad array comprising a plurality of conductive bottom pads; and a micro LED array formed on the IC backplane, the micro LED array including a plurality of the above described micro LEDs; wherein one micro LED of the plurality of micro LEDs is electrically connected with one bottom pad of the plurality of conductive bottom pads.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1A illustrates a structural diagram showing an exemplary micro LED, according to some embodiments of the present disclosure.

FIG. 1B illustrates a structural diagram showing further details of the exemplary micro LED illustrated in FIG. 1A, according to some embodiments of the present disclosure.

FIG. 2A illustrates a structural diagram showing another exemplary micro LED, according to some embodiments of the present disclosure.

FIG. 2B illustrates a structural diagram showing further details of the exemplary micro LED illustrated in FIG. 2B, according to some embodiments of the present disclosure.

FIG. 3 illustrates a structural diagram showing an exemplary micro LED, according to some embodiments of the present disclosure.

FIG. 4 illustrates a structural diagram showing an exemplary micro LED, according to some embodiments of the present disclosure.

FIG. 5 illustrates a structural diagram showing an exemplary micro LED, according to some embodiments of the present disclosure.

FIG. 6 illustrates a structural diagram showing an exemplary micro LED, according to some embodiments of the present disclosure.

FIG. 7 illustrates a structural diagram showing a top view of a micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

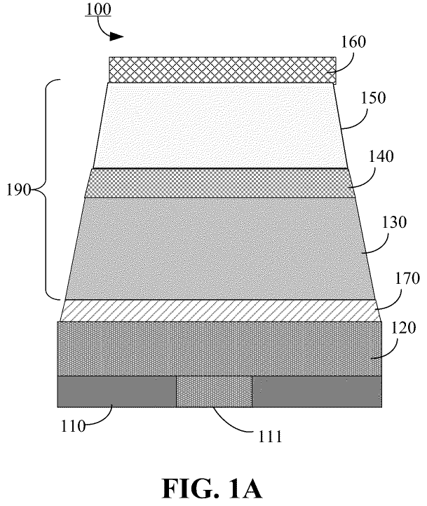

FIG. 1A illustrates a structural diagram showing an exemplary micro LED 100, according to some embodiments of the present disclosure. As shown in FIG. 1A, micro LED 100 includes a bonding layer 120 and a P-N structure 190 provided on bonding layer 120. Bonding layer 120 is used to bond P-N structure 190 with an IC backplane 110. P-N structure 190 includes a P type semiconductor layer 150, an N type semiconductor layer 130, and a light emitting layer 140 formed between P type semiconductor layer 150 and N type semiconductor layer 130. A top conductive layer 160 is formed over P-N structure 190. In this example, P-N structure 190 has a P-side up structure, that is, light emitting layer 140 is formed on N type semiconductor layer 130, and P type semiconductor layer 150 is formed on light emitting layer 140. Micro LED 100 further includes a doped P type contact layer 170 provided between N type semiconductor layer 130 and bonding layer 120. A doping concentration of doped P type contact layer 170 is in a range of 5e¹⁸ cm⁻³ to 5e²⁰ cm⁻³, for example, in a range of 2e¹⁹ cm⁻³ to 2e²⁰ cm⁻³.

FIG. 1B illustrates a structural diagram showing further details of exemplary micro LED 100 illustrated in FIG. 1A, according to some embodiments of the present disclosure. Referring to FIG. 1B, N type semiconductor layer 130 includes an N type cladding layer 132 and a doped N type contact layer 131, N type cladding layer 132 being formed on doped N type contact layer 131. In this example, doped P type contact layer 170 is provided between doped N type contact layer 131 and bonding layer 120. A doping concentration of doped N type contact layer 131 is in a range of 5e¹⁸ cm⁻³ to 5e²⁰ cm⁻³, for example, in a range of 2e¹⁹ cm⁻³ to 2e²⁰ cm⁻³. In some embodiments, bonding layer 120 includes a metal bonding layer 121 bonded with IC backplane 110 and a transparent bonding layer 122 formed on metal bonding layer 121. Doped P type contact layer 170 is provided between transparent bonding layer 122 and doped N type contact layer 131. Doped N type contact layer 131 and doped P type contact layer 170 may form a tunnel junction 180, so that doped P type contact layer 170 can directly form ohmic contact with transparent bonding layer 122. Therefore, there is no need to provide a contact metal for N-side ohmic contact formation, which may absorb and shield light output, thereby improving the light emission efficiency.

In some embodiments, material of doped N type contact layer 131 and doped P type contact layer 170 are respectively, n-GaAs and p-GaAs, or n-AlInP and p-AlInP, or n-(Al)(In)(Ga)P and p-(Al)(In)(Ga)P.

In some embodiments, a top section of micro LED 100 has a round cross section, and a diameter of a bottom surface of micro LED 100 is less than 5 μm.

In some embodiments, transparent bonding layer 122 is a TCO (transparent conductive oxide) layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, a CdO (Cadmium Oxide) layer, a GZO (Gallium doped Zinc Oxide) layer, IGZO (Indium Gallium Zinc Oxide) layer, or the like.

In some embodiments, a thickness T1 of transparent bonding layer 122 is one fourth (¼) of a wavelength of light emitted by light emitting layer 140, that is, T1=¼λ, where A is a wavelength of the light emitted by light emitting layer 140. For example, in some embodiments, when light emitted by light emitting layer 140 is red light, a wavelength of the red light is from 620 nm to 650 nm. When light emitted by light emitting layer 140 is green light, a wavelength of the green light is from 510 nm to 540 nm. When light emitted by light emitting layer 140 is blue light, a wavelength of the blue light is from 440 nm to 470 nm.

Since the thickness T1 of transparent bonding layer 122 is equal to one fourth of a wavelength of the light emitted by light emitting layer 140, metal absorption of bonding layer 120 can be reduced and a reflectivity of bonding layer 120 is increased, thereby improving the light emission efficiency.

In some embodiments, a sidewall of P type semiconductor layer 150, light emitting layer 140, and N type semiconductor layer 130 is inclined. That is, sidewalls of P type semiconductor layer 150, light emitting layer 140, and N type semiconductor layer 130 are along a straight line, and an inclined angle θ is formed between the straight line and a bottom of N type semiconductor layer 130. In some embodiments, the inclined angle θ of the sidewall is from 55 degrees to 65 degrees. Accordingly, a top surface area of P type semiconductor layer 150 is smaller than a top surface area of N type semiconductor layer 130. In some embodiments, a cross section of a top surface of micro LED 100 is a circular, and a diameter of P type semiconductor layer 150 is smaller than a diameter of N type semiconductor layer 130. Accordingly, micro LED 100 has a tapered mesa structure.

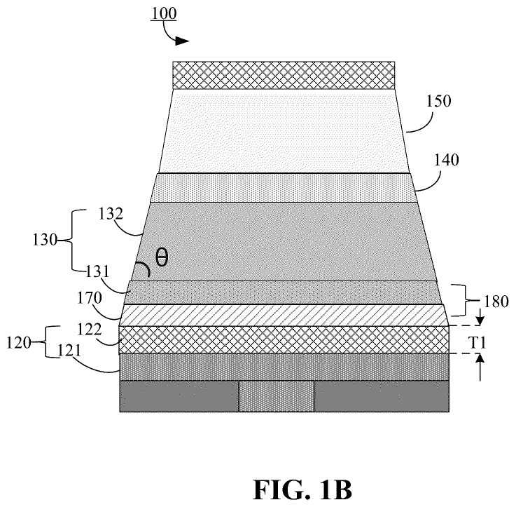

FIG. 2A illustrates a structural diagram showing another exemplary micro LED 200, according to some embodiments of the present disclosure. As shown in FIG. 2A, micro LED 200 includes a bonding layer 220 and a P-N structure 290 provided on bonding layer 220. Bonding layer 220 is used to bond P-N structure 290 with an IC backplane 210. A top conductive layer 260 is formed over P-N structure 290. P-N structure 290 includes a P type semiconductor layer 250, an N type semiconductor layer 230, and a light emitting layer 240 formed between P type semiconductor layer 250 and the N type semiconductor layer 230. In this example, P-N structure 290 has an N-side up structure, that is, light emitting layer 240 is formed on P type semiconductor layer 250, and N type semiconductor layer 230 is formed on light emitting layer 240. Micro LED 200 further includes a doped P type contact layer 270 provided between N type semiconductor layer 230 and top conductive layer 260.

FIG. 2B illustrates a structural diagram showing further details of exemplary micro LED 200 illustrated in FIG. 2A, according to some embodiments of the present disclosure. Referring to FIG. 2B, N type semiconductor layer 230 includes an N type cladding layer 232 and a doped N type contact layer 231, doped N type contact layer 231 being formed on N type cladding layer 232. In this example, doped P type contact layer 270 is provided between doped N type contact layer 231 and top conductive layer 260. Doped N type contact layer 231 and doped P type contact layer 270 may form a tunnel junction 280, so that doped P type contact layer 270 can directly form ohmic contact with top conductive layer 260. Therefore, there is no need to provide a contact metal for N-side ohmic contact formation, which may absorb and shield light output, thereby improving the light emission efficiency. In some embodiments, top conductive layer 260 is a TCO (transparent conductive oxide) layer, for example, an ITO (Indium Tin Oxide) layer, an AZO (Antimony doped Zinc Oxide) layer, an ATO (Antimony doped Tin Oxide) layer, an FTO (Fluorine doped Tin Oxide) layer, a CdO (Cadmium Oxide) layer, a GZO (Gallium doped Zinc Oxide) layer, IGZO (Indium Gallium Zinc Oxide) layer, and the like.

In some embodiments, materials of doped N type contact layer 231 and doped P type contact layer 270 are respectively n-GaAs and p-GaAs, or n-AlInP and p-AlInP, or n-(Al)(In)(Ga)P and p-(Al)(In)(Ga)P.

In some embodiments, a top section of micro LED 200 has a round cross section, and a diameter of a bottom surface of micro LED 200 is less than 5 μm.

In some embodiments, bonding layer 220 includes a metal bonding layer 221 bonded with IC backplane 210 and a transparent bonding layer 222 formed on metal bonding layer 221. A thickness T2 of transparent bonding layer 222 is one fourth (¼) of a wavelength of light emitted by light emitting layer 240, that is, T2=¼λ, where λ is a wavelength of the light emitted by light emitting layer 240. For example, in some embodiments, when light emitted by light emitting layer 240 is red light, a wavelength of the red light is from 620 nm to 650 nm. When light emitted by light emitting layer 240 is green light, a wavelength of the green light is from 510 nm to 540 nm. When light emitted by light emitting layer 240 is blue light, a wavelength of the blue light is from 440 nm to 470 nm.

Since the thickness T2 of transparent bonding layer 222 is equal to one fourth of a wavelength of the light emitted by light emitting layer 240, metal absorption of bonding layer 220 can be reduced and a reflectivity of bonding layer 220 is increased, thereby improving the light emission efficiency.

In some embodiments, a sidewall of P type semiconductor layer 250, light emitting layer 240, and N type semiconductor layer 230 is inclined. That is, sidewalls of P type semiconductor layer 250, light emitting layer 240, and N type semiconductor layer 230 are along a straight line, and an inclined angle θ is formed between the straight line and a bottom of P type semiconductor layer 250. In some embodiments, the inclined angle θ of the sidewall is from 55 degrees to 65 degrees. Accordingly, a top surface area of N type semiconductor layer 230 is smaller than a top surface area of P type semiconductor layer 250. In some embodiments, a cross section of a top surface of micro LED 200 is a circular, and a diameter of N type semiconductor layer 230 is smaller than a diameter of P type semiconductor layer 250. Accordingly, micro LED 200 has a tapered mesa structure.

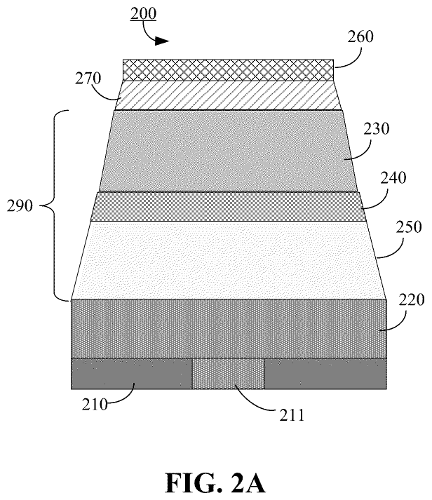

FIG. 3 illustrates a structural diagram showing an exemplary micro LED 300, according to some embodiments of the present disclosure. As shown in FIG. 3, a sidewall of a P type semiconductor layer 350, a light emitting layer 340, and an N type semiconductor layer 330 is almost vertical as viewed in FIG. 3. In some embodiments, an inclined angle θ of the sidewall is greater than 85 degrees, for example, between 85 degrees to 90 degrees. Accordingly, micro LED 300 has a vertical mesa structure, which can increase beam angle performance. Also, the light emitting area can be larger, thereby increasing the light emission efficiency. It can be understood that the inclined angle θ of the sidewall shown in FIG. 2B can also be greater than 85 degrees, for example, between 85 degrees to 90 degrees. A micro LED of which a P-N structure is N-side up structure can also have a vertical mesa structure.

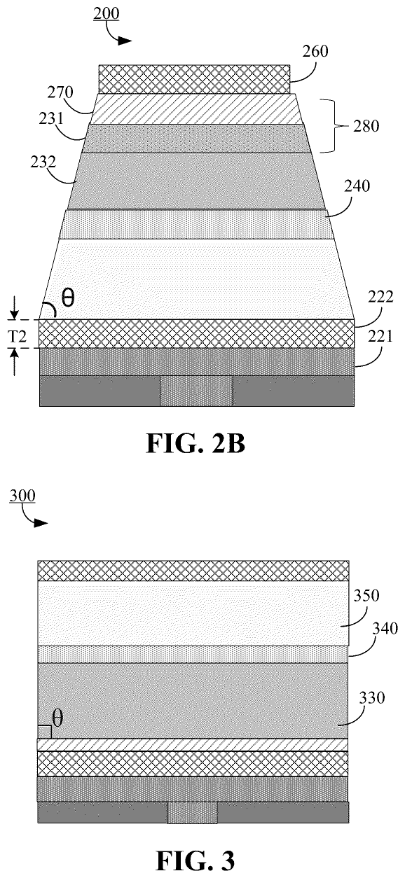

FIG. 4 illustrates a structural diagram showing an exemplary micro LED 400, according to some embodiments of the present disclosure. As shown in FIG. 4, an N type cladding layer 432 includes a distributed Bragg reflection (DBR) structure 433. DBR structure 433 may be disposed at a part of N type cladding layer 432, for example, at a bottom of N type cladding layer 432. In some embodiments, DBR structure 433 may be disposed at a top of N type cladding layer 432. In some embodiments, all of N type cladding layer 432 may be DBR structure 433. In some embodiments, DBR structure 433 includes a plurality of first layers and a plurality of second layers, the plurality of first layers and the plurality of second layers being alternately layered. In some embodiments, materials of the plurality of first layers and the plurality of second layers are AlInP and AlGaInP, respectively. In some embodiments, materials of the plurality of first layers and the plurality of second layers are AlGaAs and AlAs, respectively. Description of other features of micro LED 400 may be found by referring to such features described above with reference to FIG. 1B, which will not be repeated here.

With DBR structure 433 provided in micro LED 400, the reflectivity is increased and bottom metal absorption is reduced, thereby increasing the light emission efficiency.

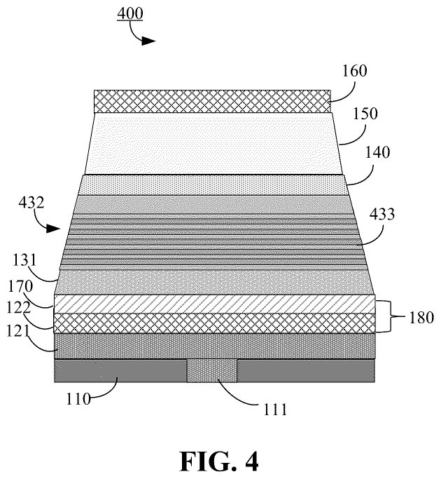

FIG. 5 illustrates a structural diagram showing an exemplary micro LED 500, according to some embodiments of the present disclosure. As shown in FIG. 5, micro LED 500 includes a bonding layer 520, which includes a transparent bonding layer 522 formed on a metal bonding layer 521, transparent bonding layer 522 being a distributed Bragg reflection (DBR) layer. The DBR layer includes a plurality of sputtered transparent bonding layers 522a and a plurality of porous transparent bonding layers 522b. The plurality of sputtered transparent bonding layers 522a and the plurality of porous transparent bonding layers 522b are alternately layered. For example, a first one of sputtered transparent bonding layers 522a is formed on metal bonding layer 521, a first one of porous transparent bonding layers 522b is formed on the first one of sputtered transparent bonding layers 522a, a second one of sputtered transparent bonding layers 522a is formed on the first one of porous transparent bonding layers 522b, a second one of porous transparent bonding layers 522b is formed on the second one of sputtered transparent bonding layers 522a, a third one of sputtered transparent bonding layers 522a is formed on the second one of porous transparent bonding layers 522b, a third one of porous transparent bonding layers 522b is formed on the third one of sputtered transparent bonding layers 522a, a fourth one of sputtered transparent bonding layers 522a is formed on the third one of porous transparent bonding layers 522b, and doped P type contact layer 570 is formed on the fourth one of sputtered transparent bonding layers 522a. A number of sputtered transparent bonding layers 522a can be equal to a number of porous transparent bonding layers 522b plus one. It can be understood that the number of sputtered transparent bonding layers 522a and the number of porous transparent bonding layers 522b are not limited herein, and can be varied according to actual practice.

In some embodiments, a refractive index of each of sputtered transparent bonding layers 522a is greater than 1.7, for example, 1.9, and a refractive index of each of porous transparent bonding layers 522b is less than 1.5. In some embodiments, the sputtered transparent bonding layers 522a and porous transparent bonding layers 522b are TCO thin film, for example, one or more of an ITO film, an AZO film, an ATO film, an FTO film, or the like. Description of other features of micro LED 500 may be found by referring to such features described above with reference to FIG. 1B, which will not be repeated here.

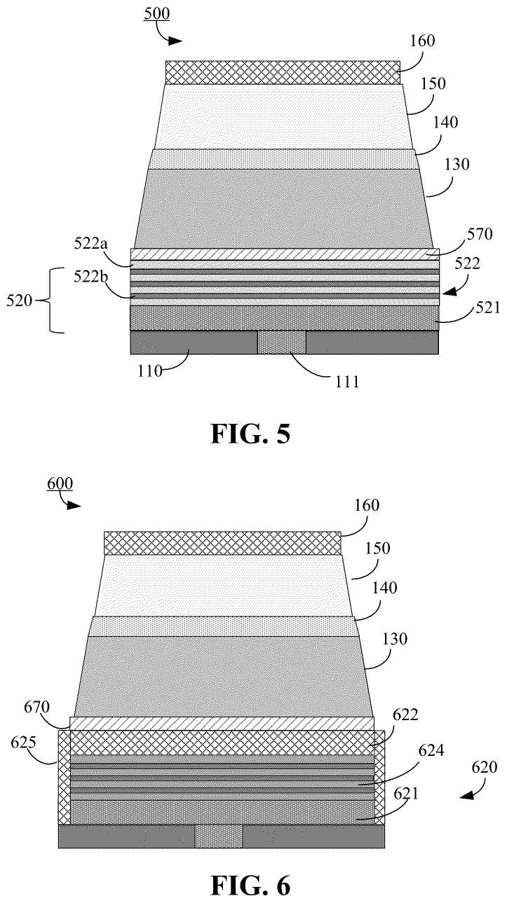

FIG. 6 illustrates a structural diagram showing an exemplary micro LED 600, according to some embodiments of the present disclosure. As shown in FIG. 6, a bonding layer 620 includes a metal bonding layer 621, a transparent bonding layer 622, and a dielectric distributed Bragg reflection (DBR) layer 624 is formed between transparent bonding layer 622 and metal bonding layer 621. A doped P type contact layer 670 is formed on transparent bonding layer 622. A side conductive structure 625 is provided surrounding DBR layer 624 for connecting transparent bonding layer 622 with metal bonding layer 621. In some embodiments, dielectric DBR layer 624 is formed by a plurality of SiO2 layers and a plurality of SiNx layers, the plurality of SiO2 layers and the plurality of SiNx layers being alternately layered. In some embodiments, a refractive index of each SiO2 layer is 1.45, and a refractive index of each SiNx layer is 2.1. In some embodiments, carriers are injected via side conductive structure 625. Therefore, a current path is formed between transparent bonding layer 622 and metal bonding layer 621.

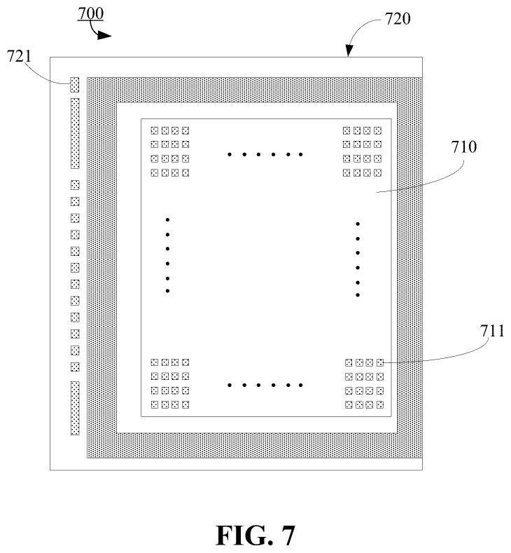

FIG. 7 illustrates a structural diagram showing a top view of a micro LED display panel 700, according to some embodiments of the present disclosure. Referring to FIG. 7, micro LED display panel 700 includes a micro LED array 710 and an IC (integrated circuit) backplane 720. Micro LED array 710 is located on IC backplane 720 to form an image display area of micro LED display panel 700. The rest of the area on IC backplane 720 not covered by micro LED array 710 is formed as a non-functional area. IC backplane 720 is formed at the back surface of micro LED array 710 with a part extending outside of, i.e., not covered by, micro LED array 710. Micro LED array 710 includes a plurality of micro LEDs 711 provided in an array. IC backplane 720 is configured to control the plurality of micro LEDs 711. IC backplane 720 may include a bottom pad array (not shown) corresponding to micro LED array 710. The bottom pad array includes a plurality of conductive bottom pads (for example, bottom pad 111 in FIG. 1A and bottom pad 211 in FIG. 2A), and one bottom pad corresponds to one micro LED 711. One micro LED 711 of the plurality of micro LEDs 711 is electrically connected with one bottom pad of the plurality of bottom pads.

In some embodiments, a top conductive layer (for example, top conductive layer 160 in FIG. 1A and top conductive layer 260 in FIG. 2A) of the micro LED is interconnected with the top conductive layer of each of the plurality of micro LEDs. That is, the top conductive layer is continuously formed on a top of micro LED array 710, and connected with every micro LED 711.

In some embodiments, IC backplane 720 further includes a top connected pad 721. The top conductive layer is connected with top connected pad 721, and further may connect to an external circuit.

Each micro LED herein (e.g., micro LEDs 100 to 600) has a very small volume. The micro LED can be applied in a micro LED display panel. The light emitting area of the micro LED display panel, e.g., micro LED display panel 700, is very small, such as 1 mm×1 mm, 3 mm×5 mm, etc. In some embodiments, the light emitting area is the area of the micro LED array in the micro LED display panel. The micro LED display panel includes one or more micro LEDs that form a pixel array in which the micro LEDs are pixels, such as a 1600×1200, 680×480, or 1920×1080-pixel array. The diameter of each micro LED is in the range of about 200 nm to 2 μm. An IC backplane, e.g., IC backplane 720, is formed at the back surface of micro LED array 710 and is electrically connected with micro LED array 710. The IC backplane acquires signals such as image data from outside via signal lines to control corresponding micro LEDs to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED comprising:
a bonding layer;
a P-N structure formed the bonding layer, wherein the P-N structure comprises a P type semiconductor layer, an N type semiconductor layer, and a light emitting layer formed between the P type semiconductor layer and the N type semiconductor layer;
a top conductive layer formed on the P-N structure; and
a doped P type contact layer, wherein if the P-N structure is a P-side up structure, the doped P type contact layer is provided between the N type semiconductor layer and the bonding layer, or
if the P-N structure is an N-side up structure, the doped P type contact layer is provided between the N type semiconductor layer and the top conductive layer.

2. The micro LED according to claim 1, wherein the N type semiconductor layer comprises an N type cladding layer and a doped N type contact layer, if the P-N structure is the P-side up structure, the N type cladding layer is formed on the doped N type contact layer and the doped P type contact layer is provided between the doped N type contact layer and the bonding layer, and
if the P-N structure is the N-side up structure, the doped N type contact layer is formed on the N type cladding layer and the doped P type contact layer is provided between the doped N type contact layer and the top conductive layer.

3. The micro LED according to claim 2, wherein materials of the doped N type contact layer and the doped P type contact layer are, respectively n-GaAs and p-GaAs, or n-AlInP and p-AlInP, or n-(Al)(In)(Ga)P and p-(Al)(In)(Ga)P.

4. The micro LED according to claim 1, wherein an inclined angle of a sidewall of the P-N structure is greater than 85 degrees.

5. The micro LED according to claim 4, wherein the sidewall of the P-N structure is vertical.

6. The micro LED according to claim 1, wherein the P-N structure has the P-side up structure, and the N type cladding layer comprises a distributed Bragg reflection (DBR) structure.

7. The micro LED according to claim 6, wherein the DBR structure comprises a plurality of first layers and a plurality of second layers, the plurality of first layers and the plurality of second layers being alternately layered.

8. The micro LED according to claim 7, wherein materials of the plurality of first layers and the plurality of second layers are, respectively, AlInP and AlGaInP, or AlGaAs and AlAs.

9. The micro LED according to claim 1, wherein the bonding layer further comprises;
a metal bonding layer; and
a transparent bonding layer formed on the metal bonding layer.

10. The micro LED according to claim 9, wherein the transparent bonding layer comprises a plurality of sputtered transparent bonding layers and a plurality of porous transparent bonding layers, the plurality of sputtered transparent bonding layers and the plurality of porous transparent bonding layers being alternately layered.

11. The micro LED according to claim 9, wherein a thickness of the transparent bonding layer is one fourth of a wavelength of light emitted by the light emitting layer.

12. The micro LED according to claim 9, wherein the bonding layer further comprises:
a dielectric distributed Bragg reflection (DBR) layer between the transparent bonding layer and the metal bonding layer; and
a side conductive structure provided on a side of the DBR layer for connecting the transparent bonding layer with the metal bonding layer.

13. A micro LED display panel comprising:
an integrated circuit (IC) backplane comprising a bottom pad array, the bottom pad array comprising a plurality of conductive bottom pads; and
a micro LED array formed on the IC backplane, the micro LED array comprising a plurality of micro LEDs;
wherein one micro LED of the plurality of micro LEDs is electrically connected with one bottom pad of the plurality of conductive bottom pads; and the micro LED comprises:
a bonding layer;
a P-N structure formed the bonding layer, wherein the P-N structure comprises a P type semiconductor layer, an N type semiconductor layer, and a light emitting layer formed between the P type semiconductor layer and the N type semiconductor layer;
a top conductive layer formed on the P-N structure; and
a doped P type contact layer, wherein if the P-N structure is a P-side up structure, the doped P type contact layer is provided between the N type semiconductor layer and the bonding layer, or
if the P-N structure is an N-side up structure, the doped P type contact layer is provided between the N type semiconductor layer and the top conductive layer.

14. The micro LED display panel according to claim 13, wherein respective top conductive layers of the plurality of micro LEDs are interconnected.

15. The micro LED display panel according to claim 14, wherein the IC backplane further comprises a top connected pad, and the respective top conductive layers are connected with the top connected pad of the IC backplane.
